(19) United States
(12) Patent Application Publication
(10) Pub. No.: US 2009/0243392 A1
(43) Pub. Date: Oct. 1, 2009

(54) METHODS FOR SHIFTING COMMON MODE BETWEEN DIFFERENT POWER DOMAINS AND APPARATUS THEREOF

(76) Inventor: Sheng-Jui Huang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/056,291

(22) Filed: Mar. 27, 2008

(51) Int. Cl. H02J 1/00; H03M 1/00

(52) U.S. Cl. 307/75; 341/141

(57) ABSTRACT

A signal processing system having different power domains is provided. The signal processing system has a first amplifier circuit operating under a first power domain; a second amplifier circuit operating under a second power domain and having a feedback configuration; a first impedance unit, coupled between an output node of the first amplifier circuit and a first input node of the second amplifier circuit; and a bias current generating circuit, coupled to the first input node of the second amplifier circuit, for providing a bias current to thereby reduce a DC current flowing through a feedback path of the second amplifier unit.

### BACKGROUND

The present invention relates to a signal processing system supplied by multiple powers, and more particularly, to methods for transferring analog signals between different power domains and related apparatus thereof.

For audio systems, such as DVD players or televisions, an analog-to-digital converter (ADC) and digital-to-analog converter (DAC) in the audio system are usually configured to deliver signals of 2V Vrms (i.e., 5.65V Vpp), so the typical power supply voltage 5V is insufficient to accommodate such a large signal swing. Therefore, the supply power voltage of the output driver is generally chosen to be 12V. Because of the extraordinarily large design rule in high voltage processes, only the output driver is given high power voltage, and other circuits are implemented in the lower voltage domain in order to save chip area and power consumption. For example, an audio system may include a low power domain operating under 3.3V and a high power domain operating under 12V. Additionally, an ADC may be defined in the low power domain for converting an analog audio signal into a digital audio signal for further signal processing, and a DAC may be defined in the high power domain for converting a processed digital signal into an analog audio signal for audio playback at an output device (e.g., a speaker). However, if no signal processing is required in certain cases, a bypass operation should be implemented to bypass the analog audio signal having a DC level equal to 1.65V due to the low power domain operating under 3.3V to be the analog audio signal having a DC level equal to 6V due to the high power domain operating under 12V.

Please refer to FIG. 1. FIG. 1 is an exemplary diagram illustrating a typical bypass circuit having two different power domains in an audio system. As shown in FIG. 1, the typical bypass circuit includes a negative feedback amplifier 101 implementing an input stage 100, and a negative feedback amplifier 121 implementing an output stage 120. It is supposed that the common modes of both of the amplifiers are set to be half of the power supply voltages LV and HV (HV>LV). Because the power supply voltage fed to the amplifier 101 in the input stage 100 is lower than the power supply voltage fed to the amplifier 121 in the output stage 120, there is a large DC current flowing from the amplifier 121 of the output stage 120 to the amplifier 101 of the input stage 100 through a negative feedback path of the amplifier 121. As a result, the amplifier 121 of the output stage 120 will amplify the common mode discrepancy. Consequently, the amplifier 121 of the output stage 120 can be easily saturated, introducing distortion to the bypassed signal due to amplifier saturation.

In the related art, adding a constant current sink and a constant current source into the bypass circuit is a common method to solve the above-mentioned problem. The constant current sink/source is utilized to providing a compensating current, of which the current value is set to be equal to the current value of the DC current generated due to the common mode discrepancy, so that the amplifier 121 of the output stage 120 would not be easily saturated due to the presence of the compensating current. However, the conventional means offers a fixed compensating current, and is unable to change in response to supply voltage variation (i.e., common mode variation). In this case, there is still a DC current flowing from the amplifier 121 of the output stage 120 to the amplifier 101 of the input stage 100 because the constant current sink/source is not capable of tracking the common mode variation of the two amplifiers 101 and 121.

### SUMMARY

It is therefore one of the objectives of the present invention to provide a method and circuit thereof to provide a compensating current capable of tracking the common mode variation of the two amplifiers operated under different power domains, to solve the above-mentioned problem.

According to an exemplary embodiment of the claimed invention, a signal processing system having different power domains is disclosed. The proposed signal processing system comprises a first amplifier circuit, a second amplifier circuit, an impedance unit and a bias current generating circuit. The first amplifier circuit operates under a first power domain. The second amplifier circuit operates under a second power domain, and has a feedback configuration. The impedance unit is coupled between an output node of the first amplifier circuit and a first input node of the second amplifier circuit. The bias current generating circuit is coupled to the first input node of the second amplifier circuit, and is used for providing a bias current to thereby reduce a DC current flowing through a feedback path of the second amplifier unit.

According to another exemplary embodiment of the claimed invention, a signal processing system having different power domains is also disclosed. The proposed signal processing system comprises a first amplifier circuit, a second amplifier circuit and a reference voltage generator. The first amplifier circuit operates under a first power domain. The second amplifier circuit operates under a second power domain, and is coupled to a reference voltage. The reference voltage generator is coupled to the second amplifier circuit, and is for setting the reference voltage to prevent the second amplifier circuit from being saturated.

According to an exemplary embodiment of the claimed invention, an N-to-M multiplexer in which M is an integer greater than 1 is disclosed. The proposed N-to-M multiplexer comprises a plurality of selecting circuits. Every selecting circuit is coupled to a plurality of input nodes for receiving a plurality of input signals, and is used for outputting an output signal according to one of the input signals. Every selecting circuit further comprises an amplifier circuit and a plurality of control circuits. The amplifier circuit has a first input node, a second input node coupled to a first reference voltage, and an output node coupled to the first input node and is utilized for outputting the output signal according to an input of the first input node. Every control circuit is coupled between the first input node of the amplifier circuit and the input nodes. Every control circuit comprises an impedance unit that is coupled to a corresponding input node, and a switch unit that selectively couples the impedance unit to the first input node of the amplifier circuit or a second reference voltage. Furthermore, when the switch unit couples the impedance unit to the first input node of the amplifier circuit, an input signal of the corresponding input node is transmitted to the first input node of the amplifier circuit, and other switch units in the same selecting circuit are coupled to the second reference voltage.

According to an exemplary embodiment of the claimed invention, a signal processing system having different power domains is disclosed. The proposed signal processing system comprises an N-to-M multiplexer in which M is an integer greater than 1, a first signal processing circuit, and a second signal processing circuit. The N-to-M multiplexer and the first signal processing circuit operate under a first power domain, and the second signal processing circuit operates under a second power domain. The N-to-M multiplexer comprises a plurality of selecting circuits including a first selecting circuit and a second selecting circuit. Every selecting circuit is coupled to a plurality of input nodes for receiving a plurality of input signals, and is used for outputting an output signal according to one of the input signals. Every selecting circuit further comprises an amplifier circuit and a plurality of control circuits. The amplifier circuit has a first input node, a second input node coupled to a first reference voltage, and an output node coupled to the first input node and utilized for outputting the output signal according to an input of the first input node. Every control circuit is coupled between the first input node of the amplifier circuit and the input nodes. Every control circuit comprises an impedance unit that is coupled to a corresponding input node, and a switch unit that selectively couples the impedance unit to the first input node of the amplifier circuit or a second reference voltage. Furthermore, when the switch unit couples the impedance unit to the first input node of the amplifier circuit, an input signal of the corresponding input node is transmitted to the first input node of the amplifier circuit, and other switch units in the same selecting circuit are coupled to the second reference voltage. The first signal processing circuit is coupled to the first selecting circuit, and is used for processing an output signal received from the first selecting circuit. The second signal processing circuit comprises a specific amplifier circuit that operates under the second power domain, an impedance unit and a bias current generating circuit. The specific amplifier circuit has a feedback configuration. The impedance unit is coupled between the second selecting circuit and a first input node of the specific amplifier circuit. The bias current generating circuit is coupled to the first input node of the specific amplifier circuit, and is used for providing a bias current to thereby reduce a DC current flowing through a feedback path of the specific amplifier unit

According to another exemplary embodiment of the claimed invention, a signal processing system having different power domains is also disclosed. The proposed signal processing system comprises an N-to-M multiplexer in which M is an integer greater than 1, a first signal processing circuit, and a second signal processing circuit. The N-to-M multiplexer and the first signal processing circuit operate under a first power domain, and the second signal processing circuit operates under a second power domain. The N-to-M multiplexer comprises a plurality of selecting circuits including a first selecting circuit and a second selecting circuit. Every selecting circuit is coupled to a plurality of input nodes for receiving a plurality of input signals, and is used for outputting an output signal according to one of the input signals. Every selecting circuit further comprises an amplifier circuit and a plurality of control circuits. The amplifier circuit has a first input node, a second input node coupled to a first reference voltage, and an output node coupled to the first input node and utilized for outputting the output signal according to an input of the first input node. Every control circuit is coupled between the first input node of the amplifier circuit and the input nodes. Every control circuit comprises an impedance unit that is coupled to a corresponding input node, and a switch unit that selectively couples the impedance unit to the first input node of the amplifier circuit or a second reference voltage. Furthermore, when the switch unit couples the impedance unit to the first input node of the amplifier circuit, an input signal of the corresponding input node is transmitted to the first input node of the amplifier circuit, and other switch units in the same selecting circuit are coupled to the second reference voltage. The first signal processing circuit is coupled to the first selecting circuit, and is used for processing an output signal received from the first selecting circuit. The second signal processing circuit comprises a specific amplifier circuit operating under the second power domain and a reference voltage generator. The specific amplifier circuit is coupled to a third reference voltage. The reference voltage generator is coupled to a second input node of the specific amplifier circuit, and is used for setting the third reference voltage to prevent the specific amplifier circuit from being saturated.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exemplary diagram illustrating a typical bypass circuit having two different power domains in an audio system.

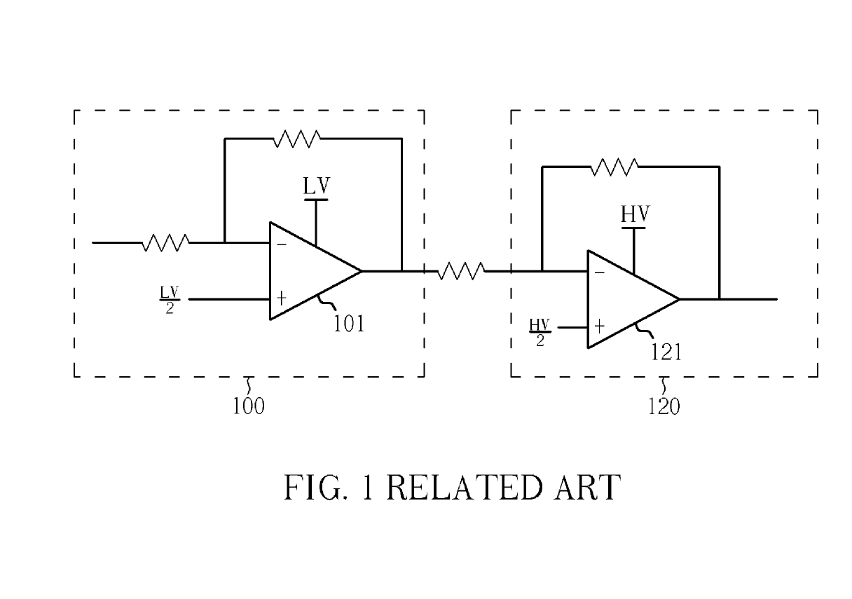

FIG. 2 is a block diagram illustrating a signal processing system having different power domains according to a first embodiment of the present invention.

FIG. 3 is a block diagram illustrating a signal processing system having different power domains according to a second embodiment of the present invention.

FIG. 4 is a simplified schematic diagram illustrating an exemplary embodiment of an N-to-M multiplexer according to the present invention.

FIG. 5 is a simplified schematic diagram illustrating a signal processing system having different power domains according to a third embodiment of the present invention.

FIG. 6 is a simplified schematic diagram illustrating a signal processing system having different power domains according to a fourth embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

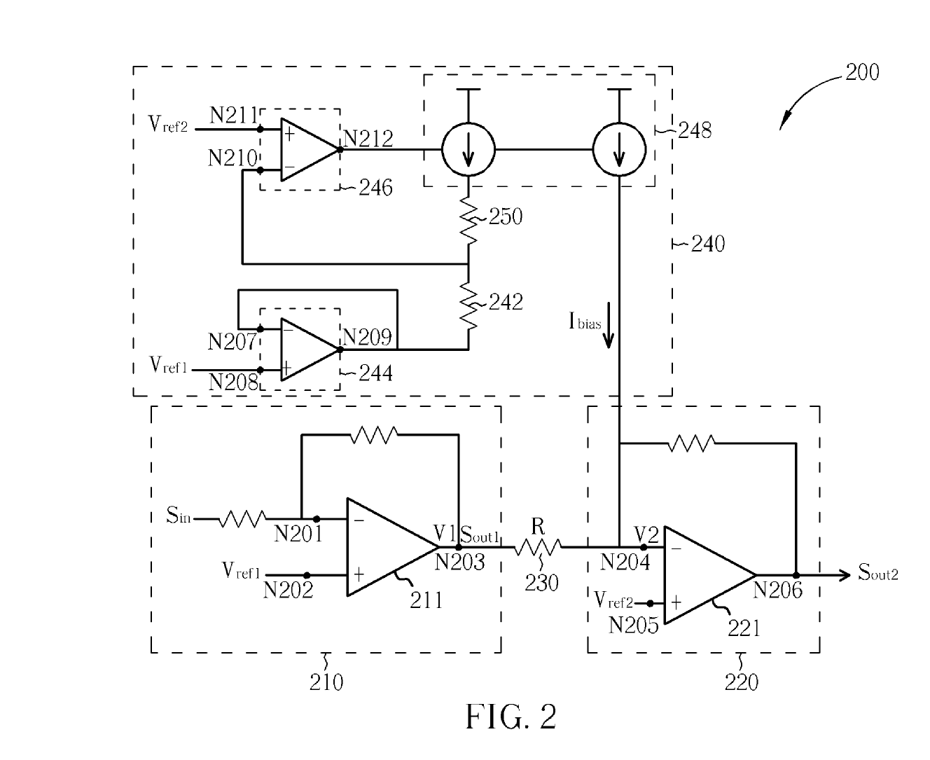

Please refer to FIG. 2. FIG. 2 is a simplified schematic diagram illustrating a signal processing system 200 having different power domains according to a first embodiment of the present invention. As shown in FIG. 2, the signal processing system 200 includes a first amplifier circuit 210, a second amplifier circuit 220, a first impedance unit 230 and a bias current generating circuit 240. The first amplifier circuit 210 operates under a first power domain, while the second amplifier circuit 220 operates under a second power domain having a power supply voltage different from that used in the first power domain. By way of example but not a limitation, the first amplifier circuit 210 shown in FIG. 2 is configured to operate under a low power domain, and the second amplifier circuit 220 is configured to operate under a high power domain. In practice, every circuit of the signal processing system 200 can be implemented respectively by individual hardware circuit components or integrating a portion of or all of the circuits of the signal processing system 200 in a single chip.

In this embodiment, the first amplifier circuit 210 has a first input node N201 for receiving an input signal Sin, a second input node N202 coupled to a first reference voltage Vref1, and an output node N203 coupled to the first input node N201 and utilized for outputting a first output signal Sout1. Due to the negative feedback configuration implemented in the first amplifier circuit 210, the first input node N201 is an inverting node of an amplifier 211, while the second input node N202 is a non-inverting node of the amplifier 211. The second amplifier circuit 220 has a first input node N204 coupled to the output node N203 of the first amplifier circuit for receiving the first output signal Sout1, a second input node N205 coupled to a second reference voltage Vref2, and an output node N206 coupled to the first input node N204 of the second amplifier circuit 220 through a feedback path and utilized for outputting a second output signal Sout2. Similarly, because of the negative feedback configuration implemented in the second amplifier circuit 220, the first input node N204 is an inverting node of an amplifier 221, while the second input node N205 is a non-inverting node of the amplifier 221. As shown in FIG. 2, the first impedance unit 230 is coupled between the output node N203 of the first amplifier circuit 210 and the first input node N204 of the second amplifier circuit 220, and the bias current generating circuit 240 is coupled to the first input node N204 of the second amplifier circuit 220.

The bias current generating circuit 240 is utilized for providing a bias current Ibias (i.e., a compensating current) to thereby reduce a DC current flowing through a feedback path of the second amplifier circuit 220. The more accurately the bias current Ibias is closer to a current value of the DC current originally flowing through the feedback path of the second amplifier circuit 220, the less the common mode discrepancy is amplified. Additionally, the current value of the DC current flowing through the feedback path of the second amplifier circuit 220 is substantially determined according to an impedance value R of the first impedance unit 230, a DC voltage level V1 at the output node N203 of the first amplifier circuit 210, and a DC voltage level V2 at the first input node N204 of the second amplifier circuit 220. The current value of the DC current flowing through the feedback path of the second amplifier circuit 220 can be estimated by the following equation:

$$I = \frac{\vert V 1 - V 2 \vert}{R} \qquad ( 1 )$$

In above equation (1), I represents the current value of the DC current flowing through the feedback path of the second amplifier circuit 220. Therefore, to minimize the common mode discrepancy amplification for preventing the amplifier 221 from saturation, it is preferable to make the current value of the bias current Ibias approximate as closely as possible to a current value represented by the equation (1).

The current generating circuit 240 is well designed to achieve this purpose. If the first amplifier circuit 210 operates under the first power domain that is a low power domain, and the second amplifier circuit 220 operates under the second power domain that is a high power domain, the bias current generating circuit 240 is defined to serve as a current source to inject the bias current Ibias into the node N204, as shown in FIG. 2. However, if the first amplifier circuit 210 operates under the first power domain that is a high power domain, and the second amplifier circuit 220 operates under the second power domain that is a low power domain, the bias current generating circuit 240 is defined to serve as a current sink for sinking the bias current Ibias from node N204. Since a skilled person can readily realize needed modifications made to the circuit configuration shown in FIG. 2 to provide a bias current generating circuit 240 acting as a current sink, further description is omitted here for brevity. The operation of the bias current generating circuit 240 shown in FIG. 2 is detailed as below.

In this embodiment, the first amplifier circuit 210 and the second amplifier circuit 220 respectively operate under a low power domain and a high power domain, so the bias current generating circuit 240 is a current source. Additionally, to further suppress distortion, a corresponding current sink (not shown) can be integrated into the amplifier 211 to sink another bias current from the node N203. As shown in FIG. 2, the current generating circuit 240 includes a second impedance unit 242, a third amplifier circuit 244, a fourth amplifier circuit 246, a current mirror circuit 248 and, optionally, a third impedance unit 250. The third amplifier circuit 244 has a first input node N207 coupled to one end of the second impedance unit 242, a second input node N208 coupled to the first reference voltage Vref1, and an output node N209 coupled to the first input node N207 of the third amplifier circuit 244. The fourth amplifier circuit 246 has a first input node N210 coupled to the other end of the second impedance unit 242, a second input node N211 coupled to the second reference voltage Vref2, and an output node N212.

The current mirror circuit 248 is coupled to at least the second impedance unit 242, and is for mirroring a current flowing through the second impedance unit 242 to generate the bias current Ibias according to a current mirror ratio. In this embodiment, the third impedance unit 250 is coupled between the current mirror circuit 248 and the second impedance unit 242, and is for noise reduction. Furthermore, provided that the current mirror ratio of the current mirror circuit 248 is equal to one, an impedance value of the second impedance unit 242 is equal to the impedance value of the first impedance unit 230. In this way, the current value of the bias current Ibias supplied by the bias current generating circuit 240 is substantially the same as the current value I represented by the aforementioned equation (1). Please note that the impedance value of the second impedance unit 242 and the current mirror ratio of the current mirror circuit 248 here are only for illustrative purposes and not meant to be taken as limitations of the present invention. In other words, provided the current value of the bias current Ibias injecting into node N204 is equal to the desired current value I represented by the aforementioned equation (1), the impedance value of the second impedance unit 242 and the current mirror ratio of the current mirror circuit 248 can be adjusted depending upon the design requirements. It should also be noted that in other embodiments the third impedance unit 250 can be omitted. In other words, the third impedance unit 250 is an optional component depending on design requirements. Additionally, in a preferred embodiment, the current value of the bias current Ibias is substantially equal to the desired current value I represented by the aforementioned equation (1) for optimum effect; however, this is not meant to be a limitation of the present invention. If the bias current Ibias is provided but its current value is less than the optimum current value defined by the above equation (1), the saturation problem of the amplifier 221 might still be completely avoided or partially alleviated under certain operating conditions. This also obeys the spirit of the present invention.

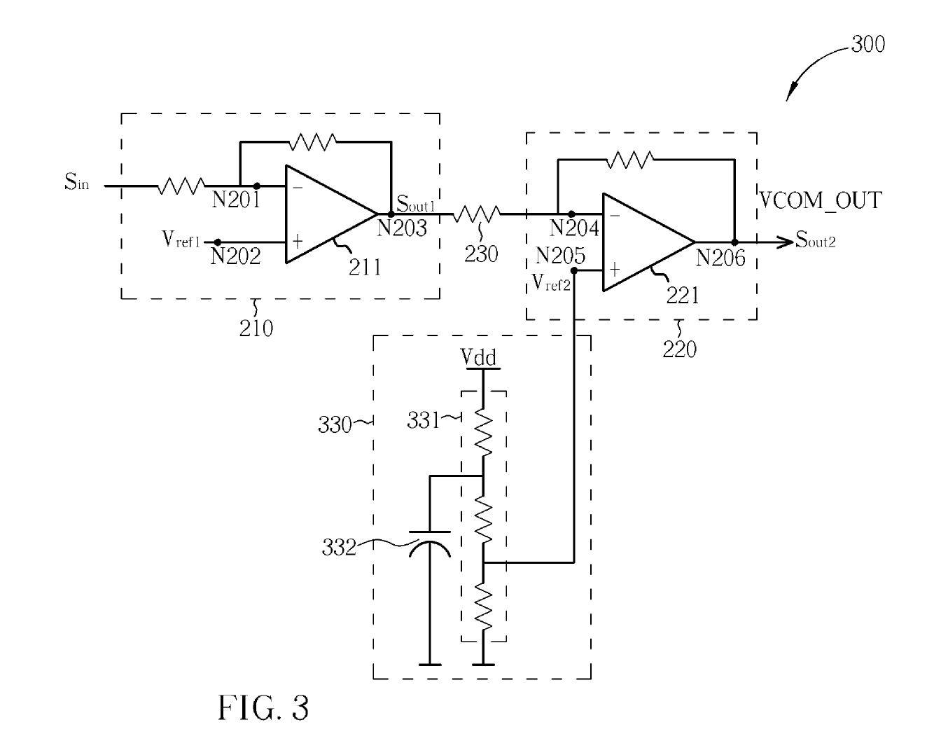

Please refer to FIG. 3. FIG. 3 is a simplified schematic diagram illustrating a signal processing system 300 having different power domains according to a second embodiment of the present invention. As shown in FIG. 3, the signal processing system 300 includes a first amplifier circuit 210, a second amplifier circuit 220 and a reference voltage generator 330. The first amplifier circuit 210 operates under a first power domain, and the second amplifier circuit 220 operates under a second power domain. As mentioned above, in one configuration, the first power domain could be a low power domain, while the second power domain could be a high power domain; however, in another configuration, the first power domain could be a high power domain, while the second power domain could be a low power domain. In practice, every circuit of the signal processing system 300 can be implemented respectively by different individual hardware circuit components or integrating a portion of or all of the circuits of the signal processing system 300 in a single chip. Since the configuration and operation of the first amplifier circuit 210 and the second amplifier circuit 220 in the FIG. 3 are similar to those illustrated above when detailing operations of the signal processing system 200 shown in FIG. 2, further description is not repeated here for the sake of brevity.

The reference voltage generator 330 is coupled to the second amplifier circuit 220, and is used for setting the second reference voltage Vref2 of the amplifier 221 with negative feedback configuration to prevent the amplifier 221 from being easily saturated due to the above-mentioned common mode discrepancy. Suppose that the first amplifier circuit 210 operates in a low power domain, the second amplifier circuit 220 operates in a high power domain, the impedance value of the first impedance unit 230 is R, and a feedback impedance value of the feedback path of the amplifier 221 is R′. The output common mode voltage VCOM_OUT at the output node N206 is expressed by the following equation:

$${V}_{COM\_OUT} = ( 1 + \frac{{R}^{′}}{R} ) {V}_{ref 2} - {V}_{ref 1} \times \frac{{R}^{′}}{R} \qquad ( 2 )$$

In view of the above equation (2), the output common mode voltage VCOM_OUT is reduced when the second reference voltage Vref2 of the second amplifier circuit 220 is lowered. In this way, the saturation problem of the amplifier 221 is completely avoided or partially alleviated if the second reference voltage Vref2 is properly set. In this embodiment, the reference voltage generator 330 sets the second reference voltage Vref2 to be lower than half of the operating voltage Vdd supplied to the reference voltage generator 330, i.e., Vref2<Vdd/2. Otherwise, provided that the first amplifier circuit 210 operates under a high power domain and the second amplifier circuit 220 operates under a low power domain, the output common mode voltage VCOM_OUT at the output node N206 is expressed by the following equation:

$${V}_{COM\_OUT} = {V}_{ref 1} \times \frac{{R}^{′}}{R} - ( 1 + \frac{{R}^{′}}{R} ) \times {V}_{ref 2} \qquad ( 3 )$$

To reduce the output common mode voltage VCOM_OUT, the reference voltage generator 330 sets the second reference voltage Vref2 to be higher than half of the operating voltage supplied to the reference voltage generator 330, i.e., Vref2>Vdd/2. Further description of reference voltage generator 330 is as below.

In this embodiment, the first power domain is a low power domain and the second power domain is a high power domain, so the reference voltage generator 330 sets the second reference voltage Vref2 to be lower than half of the operating voltage supplied to the reference voltage generator 330. In this way, the DC bias voltage level at the output node N206 of the second amplifier circuit 220 is lower than original DC level, which prevents amplified common mode discrepancy from saturating the amplifier 221 in the second amplifier circuit 220 though the output swing is not optimized. As shown in FIG. 3, the reference voltage generator 330 sets the second reference voltage Vref2 by dividing the operating voltage Vdd supplied to the reference voltage generator 330 through a voltage divider 331 consisting of resistors, and a capacitor 332 is used to filter out noise interference for smoothing the second reference voltage Vref2 fed into the amplifier 221. In an exemplary embodiment, the first amplifier circuit 210, the second amplifier circuit 220, and the voltage divider 331 are all integrated in a single chip, while the capacitor 332 of large capacitance is connected to the chip externally to save chip area.

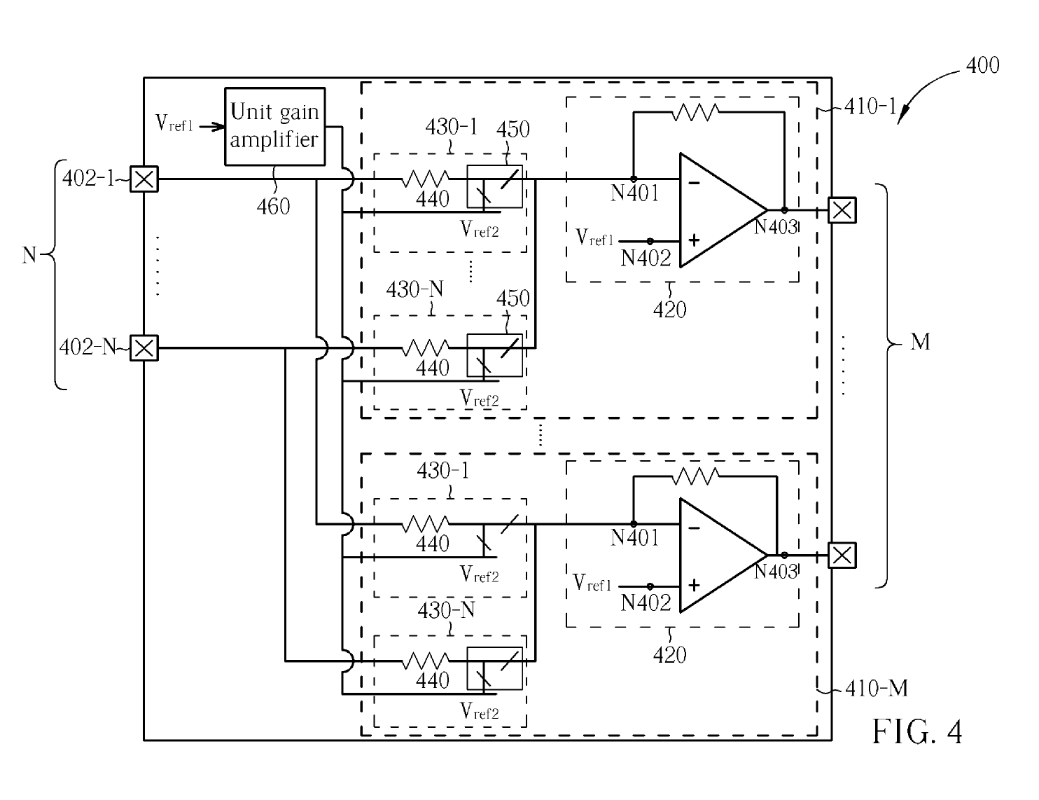

Please refer to FIG. 4. FIG. 4 is a simplified schematic diagram illustrating an exemplary embodiment of an N-to-M multiplexer 400 in which M is an integer greater than 1 according to the present invention. N and M present the input node number and the output node number of the multiplexer 400 respectively. The N-to-M multiplexer 400 includes a plurality of selecting circuits 410-1, . . . , 410-M. Only two selecting circuits are depicted for simplicity. Every selecting circuit 410-1, . . . , 410-M is coupled to a plurality of input nodes 402-1, . . . , 402-N. Similarly, only two input nodes are depicted for simplicity. Specifically, every selecting circuit is coupled to all of the input nodes for receiving a plurality of input signals, and is used for outputting an output signal according to one of the input signals. Every selecting circuit 410-1, . . . , 410-M includes an amplifier circuit 420 and a plurality of control circuits 430-1, . . . , 430-N. The amplifier circuit 420 has a first input node N401, a second input node N402 coupled to a first reference voltage Vref1, and an output node N403 coupled to the first input node N401 and utilized for outputting the output signal according to an input of the first input node N401. Every control circuit 430-1, . . . , 430-N is coupled between the first input node N401 of the amplifier circuit 420 and the input nodes 402-1, . . . , 402-N. In this embodiment, every control circuit 430-1, . . . , 430-N includes an impedance unit 440 and a switch unit 450, where the impedance unit 440 is coupled to a corresponding input node and the switch unit 450, and the switch unit 450 is used for selectively coupling the impedance unit 440 to the first input node N401 of the amplifier circuit 420 or a second reference voltage Vref2. Furthermore, when the switch unit 450 couples the impedance unit 440 to the first input node N401 of the amplifier circuit 420, an input signal of the corresponding input node (e.g., 402-1) is transmitted to the first input node N401 of the amplifier circuit 420, and other switch units in the same selecting circuit are all coupled to the second reference voltage Vref2.

By way of example but not limitation, impedance units 440 in all of the selecting circuits 430 are defined to have the same impedance value, and a unit gain amplifier 460 receives the first reference voltage Vref1 for generating the second reference voltage Vref2 equal to the first reference voltage Vref1. In this way, the input impedance values viewed at input nodes 402-1, . . . , 402-N are identical. In other words, the multiplexer configuration shown in FIG. 4 is able to keep the input impedance constant. For example, if the N-to-M multiplexer 400 is a 7-to-2 multiplexer, when it is desired to set the input impedance at any input nodes as 20K ohm, the impedance value of all of the impedance units 440 could be designed to be 20K*2=40K ohm. However, it is should be noted that the impedance value of all of the impedance units 440 designed here is not meant to be a limitation of the present invention.

In this embodiment, the N-to-M multiplexer 400 further comprises the unit gain amplifier 460 coupled to the first reference voltage Vref1 and all of switch units 450. Therefore, the unit gain amplifier 460 is used for providing the second reference voltage Vref2 with the same voltage value of the first reference voltage Vref1 to all of the switch units 450. Please note that the unit gain amplifier 460 capable of providing the second reference voltage Vref2 with the same voltage value of the first reference voltage Vref1 is not meant to be a limitation of the present invention; in other embodiments the unit gain amplifier 460 can be replaced by other kinds of circuits having the same functionality. This also obeys the spirit of the present invention.

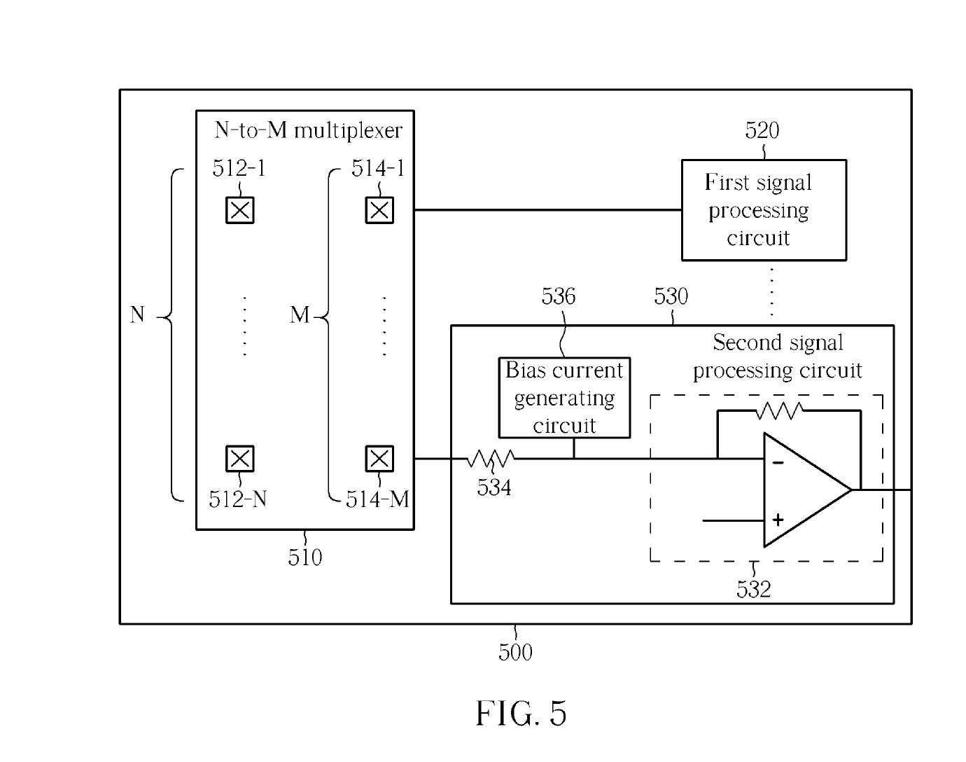

Please refer to FIG. 5. FIG. 5 is a simplified schematic diagram illustrating a signal processing system 500 having different power domains according to a third embodiment of the present invention. As shown in FIG. 5, the signal processing system 500 includes an N-to-M multiplexer 510, a first signal processing circuit 520 (e.g., an ADC) and a second signal processing circuit 530. The N-to-M multiplexer 510 and the first signal processing circuit 520 operate under a first power domain, and the second signal processing circuit 530 operates under a second power domain. In practice, every circuit of the signal processing system 500 can be implemented respectively by different individual hardware circuit components or integrating a portion of or all of the circuits of the signal processing system 500 in a single chip. Since the configuration shown in FIG. 5 is substantially based on a combination of the signal processing system 200 shown in FIG. 2 and the N-to-M multiplexer 400 shown in FIG. 4, further descriptions of the components mentioned before are not detailed here for the sake of brevity.

The N-to-M multiplexer 510 has a circuit configuration similar to that shown in FIG. 4, and only N input nodes 512-1, . . . , 512-N for receiving N input signals and M output nodes 514-1, . . . , 514-M for outputting M output signals are shown for simplicity. According to the above disclosure, each of the output nodes 514-1, . . . , 514-M can be used to output any of the input signals received at input nodes 512-1, . . . , 512-N under the control of a corresponding selecting circuit. As shown in FIG. 5, the first signal processing circuit 520 is coupled to the output node 514-1, and the second signal processing circuit 530 is coupled to the output node 514-M. Suppose the first signal processing circuit 520 is an ADC operating in a low power domain. The input signal requiring further digital signal processing is multiplexed to be an output of the output node 514-1. However, as to an input signal requiring no signal processing, the input signal is multiplexed to be an output of the output node 514-M. In this way, the input signal is bypassed. As shown in FIG. 5, the second signal processing circuit 530 includes a specific amplifier circuit 532 which has a feedback configuration, an impedance unit 534 which is coupled between the output node 514-M and a first input node of the specific amplifier circuit 532, and a bias current generating circuit 536 which is coupled to the first input node of the specific amplifier circuit 532 and is used for providing a bias current to thereby reduce a DC current flowing through a feedback path of the specific amplifier unit 532. Due to the implementation of the bias current generating circuit 536, the distortion of the bypassed signal is avoided or alleviated. Further details can be obtained from referring to the above description of the signal processing system 200 shown in FIG. 2.

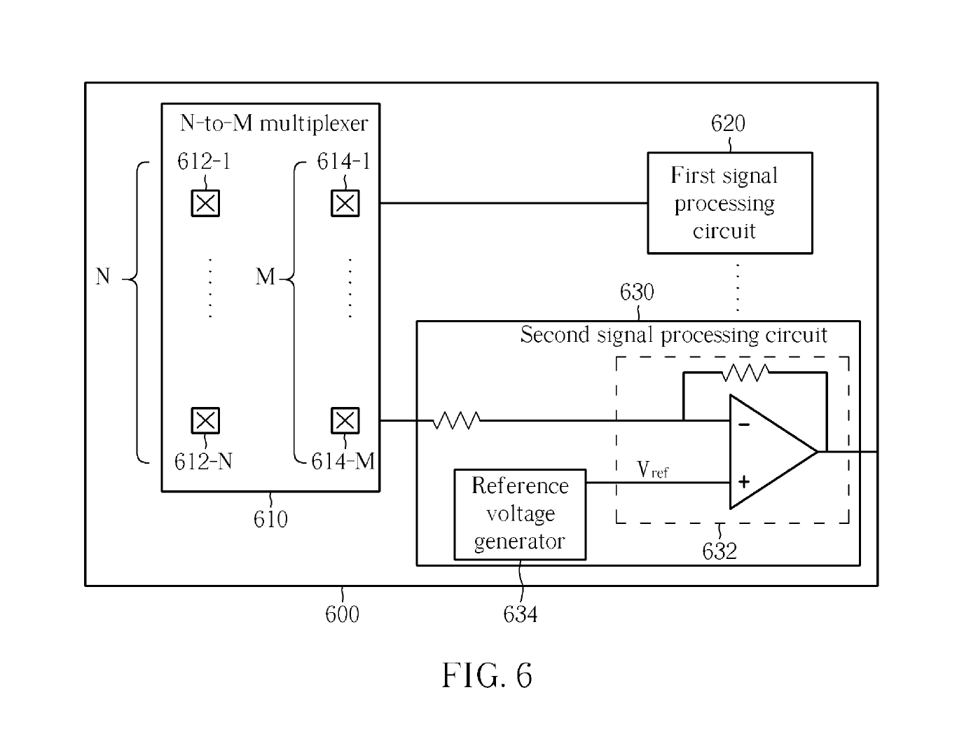

Please refer to FIG. 6. FIG. 6 is a simplified schematic diagram illustrating a signal processing system 600 having different power domains according to a fourth embodiment of the present invention. As shown in FIG. 6, the signal processing system 600 includes an N-to-M multiplexer 610, a first signal processing circuit 620 (e.g., an ADC) and a second signal processing circuit 630. The N-to-M multiplexer 610 and the first signal processing circuit 620 both operate under a first power domain, and the second signal processing circuit 630 operates under a second power domain. In practice, every circuit of the signal processing system 600 can be implemented respectively by different individual hardware circuit components or integrating a portion of or all of the circuits of the signal processing system 600 in a single chip. Since the configuration shown in FIG. 6 is substantially based on a combination of the signal processing system 300 shown in FIG. 3 and the N-to-M multiplexer 400 shown in FIG. 4, further description of the components mentioned before are not detailed here for the sake of brevity.

The N-to-M multiplexer 610 has a circuit configuration similar to that shown in FIG. 4, and only N input nodes 612-1, . . . , 612-N for receiving N input signals and M output nodes 614-1, . . . , 614-M for outputting M output signals are shown for simplicity. According to the above disclosure, each of the output nodes 614-1, . . . , 614-M can be used to output any of the input signals received at input nodes 612-1, . . . , 612-N under the control of a corresponding selecting circuit. As shown in FIG. 6, the first signal processing circuit 620 is coupled to the output node 614-1, and the second signal processing circuit 630 is coupled to the output node 614-M. Suppose the first signal processing circuit 620 is an ADC operating in a low power domain. The input signal requiring further digital signal processing is multiplexed to be an output of the output node 614-1. However, as to an input signal requiring no signal processing, the input signal is multiplexed to be an output of the output node 614-M. In this way, the input signal is bypassed. As shown in FIG. 6, the second signal processing circuit 630 includes a specific amplifier circuit 632 which is coupled to a reference voltage Vref, and a reference voltage generator 634 which is coupled to one input node of the specific amplifier circuit 632 for properly setting the reference voltage to prevent the specific amplifier circuit 632 from being easily saturated. Due to the implementation of the reference voltage generator 634, the distortion of the bypassed signal is avoided or alleviated. Further details can be obtained from referring to the above description of the signal processing system 300 shown in FIG. 3.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal processing system having different power domains, comprising:
a first amplifier circuit, operating under a first power domain;
a second amplifier circuit, operating under a second power domain and having a feedback configuration;
a first impedance unit, coupled between an output node of the first amplifier circuit and a first input node of the second amplifier circuit; and
a bias current generating circuit, coupled to the first input node of the second amplifier circuit, for providing a bias current to thereby reduce a DC current flowing through a feedback path of the second amplifier unit.

2. The signal processing system of claim 1, wherein the bias current substantially satisfies an equation as below:
$$I = \frac{\vert V 1 - V 2 \vert}{R} ,$$
where I represents a current value of the bias current, R represents an impedance value of the first impedance unit, V1 represents a voltage level at the output node of the first amplifier circuit, and V2 represents a voltage level at the first input node of the second amplifier circuit.

3. The signal processing system of claim 1, wherein the bias current generating circuit comprises:
a second impedance unit;
a third amplifier circuit, having a first input node coupled to one end of the second impedance unit, a second input node coupled to a first reference voltage, and an output node coupled to the first input node of the third amplifier circuit;
a fourth amplifier circuit, having a first input node coupled to the other end of the second impedance unit, a second input node coupled to a second reference voltage, and an output node coupled to the first input node of the fourth amplifier circuit; and
a current mirror circuit, coupled to the second impedance unit, for mirroring a current flowing through the second impedance unit to generate the bias current.

4. The signal processing system of claim 3, wherein the bias current generating circuit further comprises:
a third impedance unit, coupled between the current mirror circuit and the second impedance unit, for noise reduction.

5. A signal processing system having different power domains, comprising:
a first amplifier circuit, operating under a first power domain;
a second amplifier circuit, operating under a second power domain and coupled to a reference voltage; and
a reference voltage generator, coupled to the second amplifier circuit, for setting the reference voltage to prevent the second amplifier circuit from being saturated.

6. The signal processing system of claim 5, wherein when the first power domain is a low power domain and the second power domain is a high power domain, the reference voltage generator sets the reference voltage to be lower than half of an operating voltage supplied in the second power domain.

7. The signal processing system of claim 5, wherein when the first power domain is a high power domain and the second power domain is a low power domain, the reference voltage generator sets the reference voltage to be higher than half of an operating voltage supplied in the second power domain.

8. An N-to-M multiplexer, M being an integer greater than 1, the N-to-M multiplexer comprising:
a plurality of selecting circuits, each selecting circuit coupled to a plurality of input nodes for receiving a plurality of input signals and outputting an output signal according to one of the input signals, each selecting circuit comprising:
an amplifier circuit, having a first input node, a second input node coupled to a first reference voltage, and an output node coupled to the first input node and utilized for outputting the output signal according to an input of the first input node;
a plurality of control circuits, coupled between the first input node of the amplifier circuit and the input nodes, each control circuit comprising:
an impedance unit, coupled to a corresponding input node; and
a switch unit, selectively coupling the impedance unit to the first input node of the amplifier circuit or a second reference voltage, wherein when the switch unit couples the impedance unit to the first input node of the amplifier circuit, an input signal of the corresponding input node is transmitted to the first input node of the amplifier circuit, and other switch units in the same selecting circuit are coupled to the second reference voltage.

9. The N-to-M multiplexer of claim 8, further comprising:
a unit gain amplifier, coupled to the first reference voltage, for generating the second reference voltage according to the first reference voltage.

10. The N-to-M multiplexer of claim 9, wherein impedance units in all of the selecting circuits have the same impedance value.

11. A signal processing system having different power domains, comprising:
an N-to-M multiplexer, M being an integer greater than 1, the N-to-M multiplexer operating under a first power domain and comprising a plurality of selecting circuits including a first selecting circuit and a second selecting circuit, each of the selecting circuits coupled to a plurality of input nodes for receiving a plurality of input signals and outputting an output signal according to one of the input signals, each of the selecting circuits comprising:
an amplifier circuit, having a first input node, a second input node coupled to a first reference voltage, and an output node coupled to the first input node and utilized for outputting the output signal according to an input of the first input node; and
a plurality of control circuits, coupled between the first input node of the amplifier circuit and the input nodes, each control circuit comprising:
an impedance unit, coupled to a corresponding input node; and
a switch unit, selectively coupling the impedance unit to the first input node of the amplifier circuit or a second reference voltage, wherein when the switch unit couples the impedance unit to the first input node of the amplifier circuit, an input signal of the corresponding input node is transmitted to the first input node of the amplifier circuit, and other switch units in the same selecting circuit are coupled to the second reference voltage;
a first signal processing circuit, operating under the first power domain and coupled to the first selecting circuit, for processing an output signal received from the first selecting circuit; and
a second signal processing circuit, comprising:
a specific amplifier circuit, operating under a second power domain and having a feedback configuration;
an impedance unit, coupled between the second selecting circuit and a first input node of the specific amplifier circuit; and
a bias current generating circuit, coupled to the first input node of the specific amplifier circuit, for providing a bias current to thereby reduce a DC current flowing through a feedback path of the specific amplifier unit.

12. A signal processing system having different power domains, comprising:
an N-to-M multiplexer, M being an integer greater than 1, the N-to-M multiplexer operating under a first power domain and comprising a plurality of selecting circuits including a first selecting circuit and a second selecting circuit, each of the selecting circuits coupled to a plurality of input nodes for receiving a plurality of input signals and outputting an output signal according to one of the input signals, each of the selecting circuits comprising:
an amplifier circuit, having a first input node, a second input node coupled to a first reference voltage, and an output node coupled to the first input node and utilized for outputting the output signal according to an input of the first input node; and
a plurality of control circuits, coupled between the first input node of the amplifier circuit and the input nodes, each control circuit comprising:
an impedance unit, coupled to a corresponding input node; and
a switch unit, selectively coupling the impedance unit to the first input node of the amplifier circuit or a second reference voltage, wherein when the switch unit couples the impedance unit to the first input node of the amplifier circuit, an input signal of the corresponding input node is transmitted to the first input node of the amplifier circuit, and other switch units in the same selecting circuit are coupled to the second reference voltage;
a first signal processing circuit, operating under the first power domain and coupled to the first selecting circuit, for processing an output signal received from the first selecting circuit; and
a second signal processing circuit, comprising:
a specific amplifier circuit, operating under a second power domain and coupled to a third reference voltage; and
a reference voltage generator, coupled to a second input node of the specific amplifier circuit, for setting the third reference voltage to prevent the specific amplifier circuit from being saturated.
